(19) United States
(12) Patent Application Publication
(10) Pub. No.: US 2026/0235674 A1
(43) Pub. Date: Aug. 13, 2026

(54) CLOCK GATING BASED ON CARE BITS IN SCAN CHAINS FOR REDUCED CLOCK POWER DURING SCAN AUTOMATIC TEST PATTERN GENERATION

(71) Applicant: Texas Instruments Incorporated, Dallas, TX (US)

(72) Inventors: Arshdeep Singh, RUDRAPUR (IN); Navaneeth R, YELAHANKA BANGALORE (IN); Vishal Diwan, Bangalore (IN)

(21) Appl. No.: 19/051,371

(22) Filed: Feb. 12, 2025

(51) Int. Cl. G01R 31/3185; G01R 31/317

(52) U.S. Cl. CPC G01R 31/318536; G01R 31/31727

(57) ABSTRACT

An electronic device includes a scan chain having a scan chain data input and storage elements with respective storage element clock inputs, a pattern gating circuit having a pattern gating register, and a clock gating circuit configured to selectively prevent coupling of a system clock to the storage element clock inputs during a scan of the scan chain based on a value of the pattern gating register. A system includes automatic test equipment having a scan data output and the electronic device having a decompressor coupled to the scan data output of the ATE with the pattern gating circuit coupled to the scan data output of the decompressor.

### BACKGROUND

Electronic devices are designed for operation within a power budget based on specified operating parameters and functional performance requirements. For example, highly integrated devices, such as systems on chip (SoC) devices have stringent power requirements and are usually designed to support a specific peak functional power requirement. Manufacturing electronic devices can include verifying integrated circuit functionality using built in self-test (BIST) circuitry to test flip-flops, registers, memories or other storage elements. Manufacturing testing is preferably fast, with multiple storage elements interconnected in scan chains. Scan data patterns are provided to scan chain inputs, and the storage elements are clocked to allow data patterns to propagate through tested storage elements. The states or outputs of the scan chain storage elements can be compared with expected results to determine failures. Although high-speed scan operation can help reduce test cost, faster self-test scanning can increase the probability of scan shift power (during test mode) exceeding the functional power specifications of a tested device design.

### SUMMARY

In one aspect, an electronic device includes a scan chain having a scan chain data input and storage elements with respective storage element clock inputs, as well as a pattern gating circuit having a pattern gating register, and a clock gating circuit configured to selectively prevent coupling of a system clock to the storage element clock inputs during a scan of the scan chain based on a value of the pattern gating register.

In another aspect, a system includes automatic test equipment (ATE) having a scan data output, and a tested device that includes a decompressor coupled to the scan data output of the ATE, a scan chain having a scan chain data input and storage elements with respective storage element clock inputs, a pattern gating circuit coupled to the scan data output of the decompressor and having a pattern gating register, and a clock gating circuit configured to selectively prevent coupling of a system clock to the storage element clock inputs during a scan of the scan chain based on a value of the pattern gating register.

In a further aspect, a method includes selectively gating a scan chain data input of a scan chain of the electronic device based on a value of a pattern gating register of the electronic device, and selectively gating storage element clock inputs of the scan chain based on the value of the pattern gating register.

### BRIEF DESCRIPTION OF THE DRAWINGS

FIG. 1 is a schematic diagram of a test system with an installed electronic device.

FIG. 1A is a schematic diagram of a pattern gating circuit of the electronic device of FIG. 1.

FIG. 1B is a schematic diagram of a clock gating circuit of the electronic device of FIG. 1.

FIG. 1C is a state diagram of a finite state machine implementation of the clock gating circuit of the electronic device of FIG. 1.

FIG. 1D is a signal diagram of example scan chain clock signals and low power gating register values for three example scans in the electronic device of FIG. 1.

FIG. 1E is a schematic diagram of distributed clock gating circuitry in the electronic device of FIG. 1.

FIG. 1F is a schematic diagram of dedicated pattern gating circuits for each scan chain in an implementation of the electronic device of FIG. 1.

FIG. 1G is a schematic diagram of shared pattern gating circuits for equally sized groups of scan chains in another implementation of the electronic device of FIG. 1.

FIG. 1H is a schematic diagram of shared pattern gating circuits for differently sized groups of scan chains in another implementation of the electronic device of FIG. 1.

FIG. 2 is a flow diagram of a method of manufacturing an electronic device.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means +/−10 percent of the stated value. One or more structures, features, aspects, components, etc., may be referred to herein as first, second, third, etc., such as first and second terminals, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

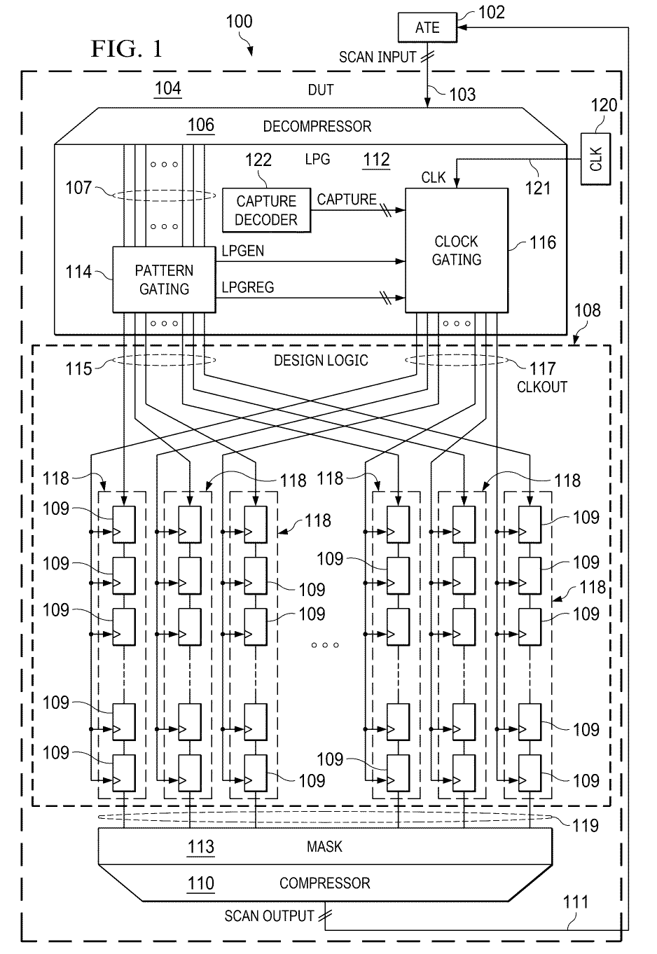

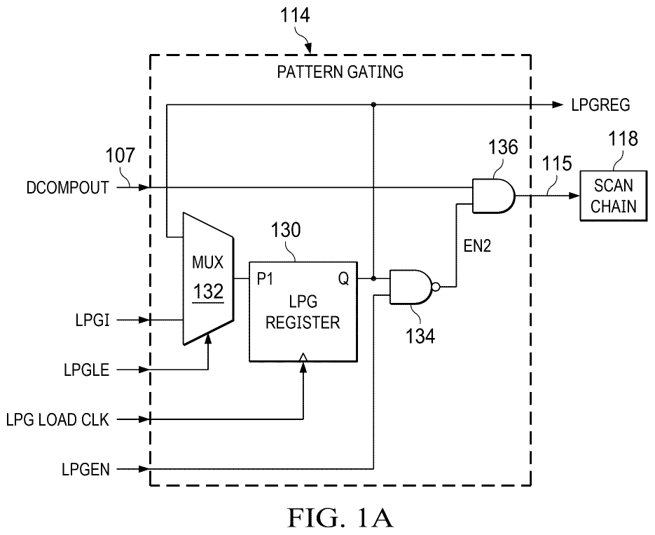

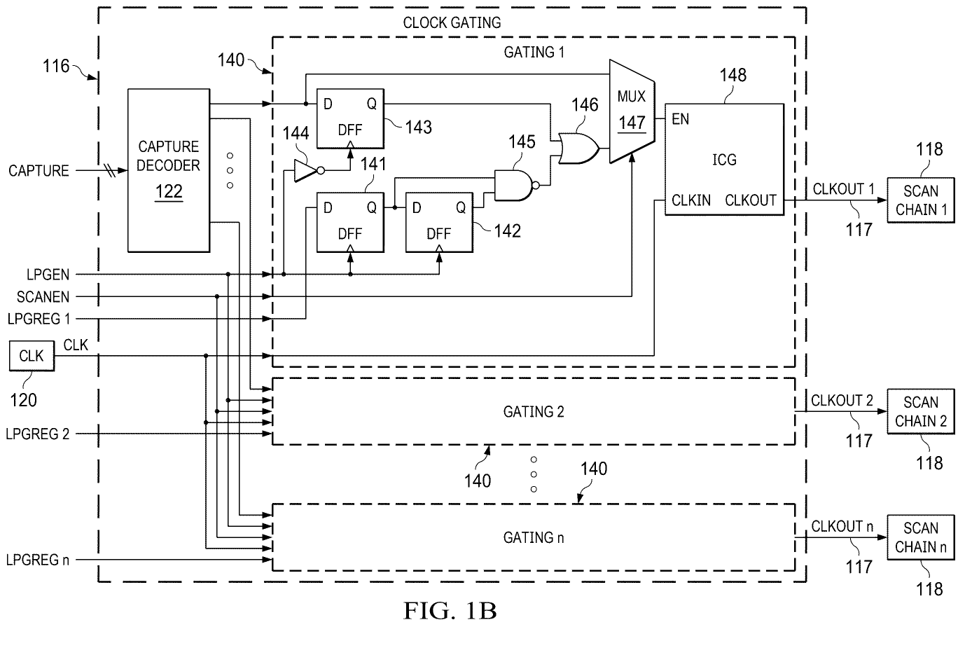

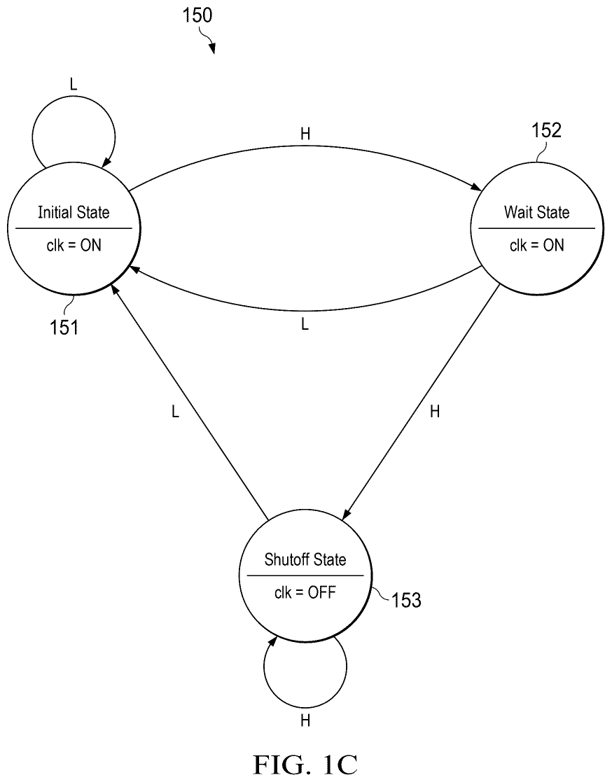

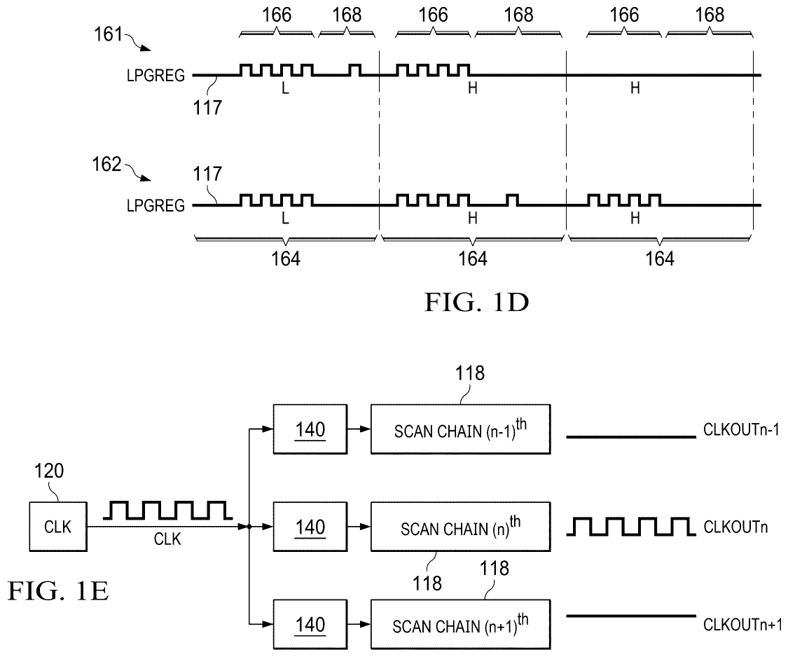

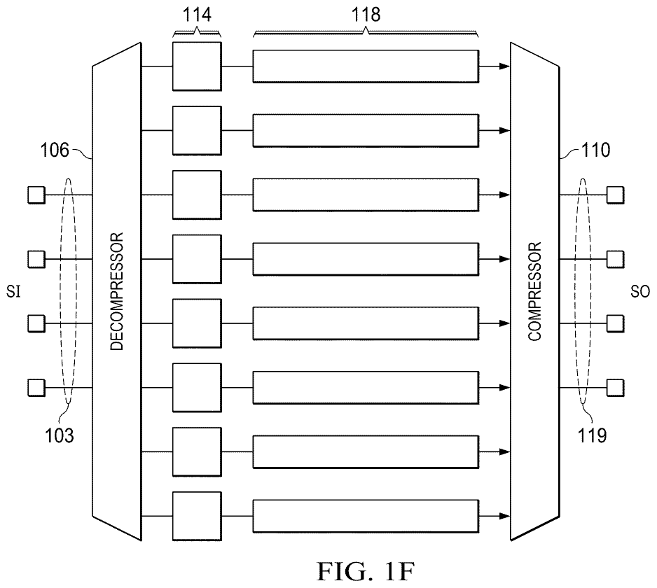

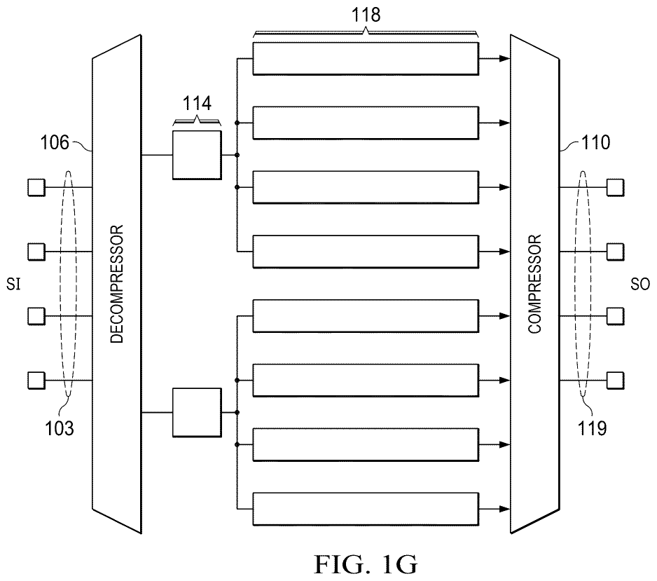

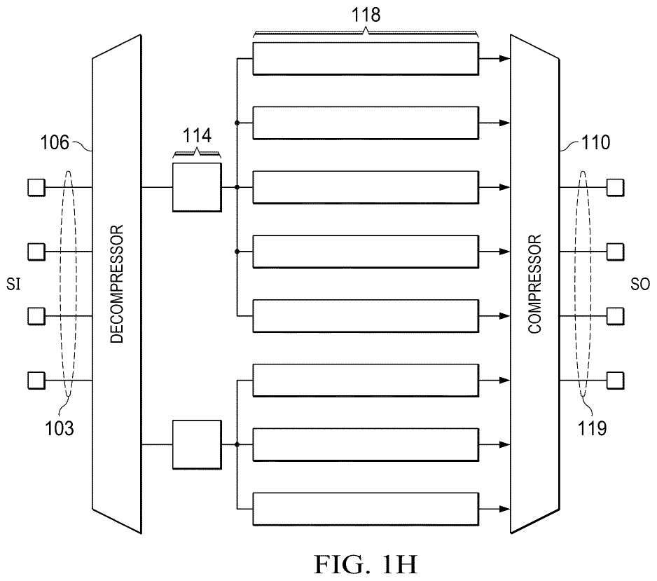

Referring to FIGS. 1-1H, FIG. 1 shows a test system 100 with an installed electronic device 102. The test system 100 is part of or associated with a manufacturing facility or organization downstream of production and packaging operations to test operation of a packaged electronic device 104. The electronic device 104 may also be referred to as a tested device or a device under test (e.g., labeled “DUT” in FIG. 1) and may be of various different forms of electronic circuits, such as an integrated circuit. The electronic device 104 is installed in a test apparatus, for example, using a socket (not shown) into which the tested electronic device 104 is inserted for production testing. The socket provides electrical connections for power and signals between automatic test equipment (ATE) 102 having a scan data output 103 that provides test signals (e.g., scan data and/or commands) to the electronic device 104.

The ATE 102 may be programmed by separate vendor tools with or may itself create automatic test pattern generation (ATG) and/or create various scan in sequence (SIS) data, also referred to as scan input data and labeled “SCAN INPUT” in FIG. 1. The scan input data can be incorporated into a test description language (TDL) that is used to evaluate the electronic device 104. The scan input data in one example includes a series of binary 0 and 1 values to be scanned into one or more scan chains 118 in the electronic device 104. Individual scan chain 118 in the electronic device 104 include a number of series connected, multiplexed-input, storage devices 109 (e.g., flip flops, registers, etc.), in which the Q output of one storage device 109 is connected to the D/SD input of a next successive storage device in the scan chain 118. A final storage device 109 in the scan chain 118 provides the data output for the chain. The individual storage devices 109 in the scan chain 118 may be concurrently clocked so that data shifts along and out of the scan chain 118 in similar fashion to operation of a shift register.

The scan data output 103 provides the scan input data to a decompressor 106 of the electronic device 104. The decompressor 106 has decompressor outputs 107 to provide decompressor output signals to scan chain storage devices 109 in a design logic block 108 (e.g., labeled “DESIGN LOGIC” in FIG. 1) for testing. The final storage devices 109 of the scan chains 118 output provide outputs 119 coupled to a compressor 110 (sometimes also referred to as a compactor) via a mask 112. The compressor 110 has a data output 111 that outputs scan results (labeled “SCAN OUTPUT” in FIG. 1). The ATE 102 or other consuming system can evaluate the scan output data from the compressor 110 in reference to the scan input data provided to the decompressor 106 to identify any failed storage devices 109 in the design logic block 108. The decompressor 106 in one example provides selective switching, such as by multiplexers or exclusive-OR (XOR) gates or flip-flop based state machines that can implement linear feedback shift register (LFSR) pseudo-random pattern generators to provide data to various different scan chain flip flops or other storage devices 109 connected to nodes of the design logic block 108. Scan data may be selectively provided (e.g., by switching circuitry) to different storage devices 109, and from there to nodes in the design logic block 108.

The compressor 110 in one example includes circuitry (e.g., multiplexers, XOR gates, flip-flop based state machines, etc.) configured to implement multiple input shift register based compactors configured to select data states at various flip flop outputs of the scan chains 118 as received from nodes in the design logic block 108, for output. For example, once circuitry within the design logic block 108 is operated (e.g., clocked for a cycle), scan chain outputs connected to that circuitry may be selected by the compressor 110, and the data at those nodes can be input to respective circuit stages for capturing followed by successive clocking to shift a captured data set to provide respective scan out sequences (SOS). The electronic device 104 has a system clock 120 with a clock output 121 that provides a system clock signal (e.g., labeled “CLK” in FIG. 1). In a test mode during manufacturing testing, the system clock signal CLK may be provided by the ATE 102 or also can be optionally generated internally as shown in FIG. 1. The decompressor 106 of the tested electronic device 104 is coupled to the scan data output 103 of the ATE 102, and the scan chains 118 have corresponding scan chain data inputs and the storage elements 109 of the respective scan chains 118 have storage element clock inputs.

The electronic device 104 also includes a low power gating circuit 112 (e.g., labeled “LPG” in FIG. 1) coupled between the scan chains 118 of the design logic block 108 and the decompressor outputs 107 of the decompressor 106. The low power gating circuit 112 helps lower the power consumption of the electronic device 104 during automated testing during manufacturing with the ATE 102 and may provide similar benefits during any post-manufacturing self-testing performed once the electronic device 104 is installed in a host system (not shown). As further shown in FIG. 1, the low power gating circuit 112 has a pattern gating circuit 114 with outputs 115 coupled to the scan data inputs of the respective scan chains 118. The pattern gating circuit 114 is configured to selectively gate the data inputs of the scan chains 118. The low power gating circuit 112 also includes a clock gating circuit 116 with an input coupled to the system clock output 121 of the system clock 120 and clock outputs 117 coupled to the clock inputs of respective scan chains 118. In addition, the example low power gating circuit 112 has a capture decoder 122 with outputs that provide respective capture signals (e.g., labeled “CAPTURE” in FIG. 1) to the clock gating circuit 116. The clock gating circuit 116 receives a low power gating enable signal (e.g., labeled “LPGEN” in FIG. 1 from the pattern gating circuit 114, and receives low power gating register values (e.g., labeled “LPGREG” in FIG. 1) from the pattern gating circuit 114.

Referring to FIGS. 1, 1A and 1F-1H, the pattern gating circuit 114 includes a pattern gating register 130 and associated circuitry (FIG. 1A) corresponding to individual scan chains 118 or groups of scan chains 118. Any suitable pattern gating and scan chain grouping arrangement can be used, examples of which are further shown in FIGS. 1F-1H. FIG. 1F shows one example of a one-to-one arrangement with dedicated pattern gating circuits 114 for each scan chain 118 in an implementation of the electronic device 104. FIG. 1G shows a shared configuration with a shared pattern gating circuit 114 for equally sized groups of four scan chains 118 in another implementation of the electronic device 104. FIG. 1H shows another non-limiting example, in which pattern gating circuits 114 are shared by differently sized groups of scan chains 118.

FIG. 1A shows one example implementation of the pattern gating circuit 114 with a pattern gating register 130 (e.g., labeled “LPG REGISTER”) for each scan chain 118 or for a group of scan chains 118. The example low power gating register 130 has a data input (e.g., labeled “P1” in FIG. 1A), a data output (e.g., labeled “Q”) and a clock input. The Q data output of the low power gating register 130 provides a low power gating register value LPGREG to control data gating of the associated scan chain(s) 118. The data input of the low power gating register 130 is loaded by an output of a multiplexer 132 (e.g., labeled “MUX”). The multiplexer 132 has a control or enable input coupled to a low power gating load enable signal LPGLE, a first input coupled to receive a low power gating input signal LPGI, and a second input coupled to the Q output of the low power gating register 130 to receive the low power gating register value LPGREG. The multiplexer allows a new LPG input value LPGI to be loaded in response to a first state or level of the low power gating load enable signal LPGLE. The low power gating register 130 loads the multiplexer output value responsive to a clock edge of a low power gating load clock signal LPG LOAD CLK.

The pattern gating circuit 114 in FIG. 1A has a NAND gate 134 and an AND gate 136. The NAND gate 134 has a first input coupled to the low power gating enable signal LPGEN, and a second input coupled the Q output of the low power gating register 130 to receive the low power gating register value LPGREG. The AND gate 136 has a first input coupled to the output of the NAND gate 134 to receive an enable signal EN2, and a second input coupled to a corresponding one of the decompressor outputs 107 (e.g., labeled “DCOMPOUT” in FIG. 1A). The output of the AND gate 136 is coupled to a respective one of the pattern gating circuit outputs 115 coupled to the scan data input of the respective scan chain 118. The low power gating register 130 stores a binary state having one of a first value (e.g., “high” or “H” or “1”) and a different second value (e.g., “low” or “L” or “0”). The pattern gating circuit 114 is configured to selectively prevent transfer of the scan data (DCOMPOUT) from the decompressor 106 to the scan chain data input of the scan chain 118 in response to the pattern gating register 130 having the first value (e.g., H) in a current scan 164. The example low power gating register 130 and associated circuitry in FIG. 1A selectively gates the heads of scan chains 118, for example, which do not contain any care bits to a constant value for the duration of a pattern. Where the corresponding scan chain 118 is to be tested, the pattern gating circuit 114 allows scan data to be delivered to the data input of the corresponding scan chain 118 in response to the pattern gating register 130 having the second value (e.g., L) in the current scan 164.

The selective scan data gating efficiently reduces the scan switching activity of the storage elements 109 of a given gated scan chain 118 and thus the shift power of the electronic device 104 under test. Moreover, the LPG registers 130 of the device 104 control which channels are gated when the gating logic is enabled. In one example, the low power gating load enable signal LPGLE controls loading of the low power gating register 130 (e.g., LPGLE is high or “1” and LPGEN is low or “0”) and can be implemented as top ports at the input of the corresponding scan chain 118 and/or in pseudo static control logic. In one example, the low power gating enable signal LPGEN selectively enables the LPG logic gates 134 and 136 in FIG. 1A and be implemented as top ports at the input of the corresponding scan chain 118 and/or in pseudo static control logic. In one example, the low power gating load clock signal LPG LOAD CLK operates as a clock for loading the low power gating register 130 and may be implemented as top ports at the input of the corresponding scan chain 118 and/or in pseudo static control logic. In another example, a DFT clock used for masking registers 112 (FIG. 1) can also be used as a source of the low power gating load clock signal LPG LOAD CLK in FIG. 1A.

Referring to FIGS. 1-1E, the clock gating circuit 116 advantageously further reduces power consumption during testing, alone or in combination with power savings achieved by operation of the pattern gating circuit 114. As shown in FIGS. 1 and 1B, the clock gating circuit 116 includes a first input coupled to the system clock 120, a second input coupled to the pattern gating register 130, and an output 117 coupled to the storage element clock inputs of the respective scan chains 118. Various enable and/or control signals are provided to the clock gating circuit 116 and to the pattern gating circuit 114 in the illustrated example, which can be generated by circuitry of the ATE 102 (FIG. 1) and/or by circuitry of the electronic device 104. FIG. 1B shows further details of an example implementation of the clock gating circuit 116.

The clock gating circuit 116 is configured to selectively prevent coupling of the system clock 120 to the storage element clock inputs during a scan 164 of the scan chain 118 based on the value of the pattern gating register 130. In this manner, the selective clock gating mitigates switching loss and power consumption of the storage elements 109 of a given scan chain 118. In one implementation, the clock gating circuit 116 includes clock gating circuitry 140 for each scan chain 118 or group of scan chains 118 (e.g., labeled “GATING 1”, “GATING 2”, . . . , “GATING n” in FIG. 1B). In different implementations, any suitable clock gating and scan chain grouping arrangement can be used, for example, where the clock gating circuit 116 operates based on the low power gating register value of a corresponding pattern gating circuit 114, and example clock gating and scan chain groupings can correspond to the non-limiting examples described above in connection with FIGS. 1F-1H (e.g., one-to-one arrangement in FIG. 1F with one clock gating circuit 140 of FIG. 1B for each scan chain 118, shared configurations with a shared clock gating circuit 140 for equally sized groups of four scan chains 118 (FIG. 1G) and/or clock gating circuits 140 shared by differently sized groups of scan chains 118 (FIG. 1H)).

The individual clock gating circuits 140 of FIG. 1B have a respective clock output 117 coupled to the clock inputs of the storage devices 109 of corresponding scan chain 118 to provide a corresponding clock output signal (e.g., labeled “CLKOUT1”, “CLKOUT2”, . . . , “CLKOUTn” in FIG. 1B). The clock gating circuit 116 in FIG. 1B operates according to the clock signal CLK from the system clock 120 and has a shared capture decoder 122 (e.g., labeled “CAPTURE DECODER” in FIG. 1B) that receives one or more input capture pulse signals (e.g., labeled “CAPTURE” in FIG. 1B). In one example, the capture decoder 122 operates as a “one-hot” decoder to provide an output capture pulse signal to a single one of the gating circuits 140 (e.g., only one domain gets a capture pulse). In the illustrated example, each domain (e.g., scan chain 118) has a corresponding gating circuit 140 as shown in FIG. 1B, although not a requirement of all possible implementations. The illustrated examples, moreover, provide for selective clock gating based on the state or value of a corresponding low power gating register 130 and based on a corresponding capture pulse, although not requirements of all possible implementations.

The individual gating circuits 140 in FIG. 1B have a corresponding capture input coupled to an output of the capture decoder 122, as well as an input for the low power gating enable signal LPGEN, a corresponding low power gating register output (e.g., labeled “LPGREG 1”, “LPGREG 2”, . . . , “LPGREG n” in FIG. 1B), and an input for a shared scan enable input signal SCANEN. The individual example clock gating circuits 140 of FIG. 1B include D flip-flops 141, 142 and 143, an inverter 144, a NAND gate 145, an OR gate 146, a multiplexer 147 and an integrated clock generator 148 (e.g., labeled “ICG”) 148. In one example, the other gating circuits 140 (e.g., “GATING 2”, . . . , “GATING n”) in FIG. 1B have similar components (not shown).

The flip-flops 141 and 142 have clock inputs coupled to receive the low power gating enable signal LPGEN, and the inverter 144 provides an inverted low power gating enable signal to a clock input of the third flip-flop 142. A data input (e.g., labeled “D” in FIG. 1B) of the first flip-flop 141 is coupled to the corresponding low power gating register 130 (e.g., FIG. 1A) to receive the corresponding low power gating register output (e.g., labeled “LPGREG 1”). The data output (e.g., labeled “Q” in FIG. 1B) of the first flip-flop 141 is coupled to the data input of the second flip-flop 142 and to a first input of the NAND gate 145. The data output of the second flip-flop 142 is coupled to the second input of the NAND gate 145. The data output of the third flip-flop 143 is coupled to a first input of the OR gate 146 and the output of the NAND gate 145 is coupled to a second input of the OR gate 146.

The third flip-flop 143 as a data input (e.g., labeled “D” in FIG. 1B) that is coupled to a corresponding output of the capture decoder 122. The inverter 144 has an input coupled to receive the low power gating enable signal LPGEN and an output that provides an inverted low power gating enable signal to the clock input of the third flip-flop 143. The data output (e.g., labeled “Q” in FIG. 1B) of the third flip-flop 143 is coupled to the first input of the OR gate 146. The corresponding output of the capture decoder 122 is also coupled to a first input of the multiplexer 147, and the output of the OR gate 146 is coupled to the second input of the multiplexer 147. The output of the multiplexer 147 controls the enable input of the clock generator 148 (e.g., labeled “EN”), and a clock input of the clock generator 148 (e.g., labeled “CLKIN”) is coupled to receive the system clock signal CLK from the system clock 120. As shown in FIGS. 1 and 1B, the respective clock generator 148 of each individual gating circuit 140 provides a respective clock output 117 to the storage element clock inputs of the storage devices 109 (FIG. 1) of the corresponding scan chain 118. The illustrated example provides advantageous power saving by selective scan chain device clock gating with little or no additional area overhead of the tested electronic device 102, for example, using pre-existing ICGs 148 with a modified enable path.

Referring also to FIGS. 1C and 1D, the clock gating circuit 116 includes a finite state machine 150 (FIG. 1C), implemented in one example by the flip flops 141 and 142 and the AND gate 145 of the gating circuits 140 in FIG. 1B. The clock gating circuit 116 is configured to selectively gate the storage element clocking by preventing coupling of the system clock 120 to the storage element clock inputs in response to the pattern gating register 130 having a first value (e.g., H or “1”) for two consecutive scans 164 (FIG. 1D). In addition, the illustrated gating circuits 140 provide the third flip flop 143 and the OR gate 146 to selectively inhibit or override clock gating (i.e., allow storage element clocking) by coupling the system clock 120 to the storage element clock inputs in response to a capture pulse associated with the scan chain 118 from the capture decoder 122.

FIG. 1C shows a state diagram of a finite state machine implementation 150 of the clock gating circuit 116 of the electronic device of FIGS. 1 and 1B, and FIG. 1D shows example scan chain clock signals and low power gating register values for three example scans 164 in the electronic device 104. FIG. 1C shows state transition branches or paths between the states 151-153 in response to the value LPREG (e.g., H or L) of the corresponding pattern gating register 130 in a current scan 164. FIG. 1D shows three example scans 164, each of which includes a scan data window 166 followed by a capture window 168. FIG. 1D shows two example sequences 161 and 162 that illustrate the ICG output 117 from the gating circuit 140 (e.g., CLKOUT) and the corresponding value LPGREG (e.g., H or L) of the pattern gating register 130 for three successive scans 164.

The state machine 150 of FIG. 1C has a first state 151 (e.g., labeled “Initial State/clk=ON”), a second state 152 (e.g., labeled “Wait State/clk=ON”), and a third state 153 (e.g., labeled “Shutoff State/clk=OFF”). In the first and second states 151 and 152, the gating circuit 140 (FIG. 1B) couples the system clock 120 to the storage element clock inputs during a scan 164 (FIG. 1C). In the third state 153, the gating circuit 140 (FIG. 1B) prevents coupling of the system clock 120 to the storage element clock inputs during the scan 164. In operation in the first example sequence 161 of FIG. 1D, the value LPGREG of the pattern gating register 130 is low (L) during the first scan 164, and the State machine 150 of FIG. 1C remains in the first day 151, with the gating circuit 140 (FIG. 1B) coupling the system clock 120 to the storage element clock inputs to provide the clock pulse output 117 during the scan data window 166. In this example, the capture window 168 of the first scan 164 includes a capture pulse shown in the first example sequence 161 of FIG. 1D, which is also provided at the output 117 of the gating circuit 140.

The first example sequence 161 continues for the second scan 164 with the value LPGREG of the pattern gating register 130 being high (H). The finite state machine 150 in this example transitions from the first state 151 to the second state 152 in response to the pattern gating register 130 having the first value H in the current scan 164, and the clock gating remains off, with the clock pulses being provided at the output 117 as shown in FIG. 1D. The finite state machine 150 is configured to transition from the second state 152 back to the first state 151 in response to the pattern gating register 130 having the different second value (LPGREG=L) in a current scan 164 as shown in the state machine diagram 150 of FIG. 1C. In the first example sequence 161 of FIG. 1D, however, the pattern gating register 130 remains at the first value (LPGREG=h) in the third scan 164. In response, the finite state machine 150 transitions from the second state 152 to the third state 153 in response to the pattern gating register 130 having the first value H in the current scan 164 and in the previous scan 164 (e.g., two consecutive scans with the first value H). As shown in FIG. 1D, the transition to the third state 153 starts the scan clock gating, and the output 117 of the gating circuit 150 does not provide any clock pulses during the third scan 164 in the first example sequence 161.

The finite state machine 150 is configured (e.g., by the respective first and second flip-flops 141 and 142) to remain in the third state 153 thereafter while the pattern gating register 130 continues to have the first value H in current and previous scans 164 (not shown in FIG. 1D). In addition, the finite state machine 150 is configured to transition from the third state 153 back to the first state 151 in response to the pattern gating register 130 having the second value L in the current scan 164 (not shown in the three example scans 164 of FIG. 1D). The first example sequence 161 in FIG. 1D illustrates selective clock gating based on the finite state machine 150 to enable the clock output 117 when the capture pulse is observed between L and H, and if a subsequent first value H is observed following a previous first value H, then the state machine 150 turns the clock off.

The second example sequence 162 in FIG. 1D further illustrates operation of the example state machine 150. In this example, in response to the provision of a capture pulse in the capture window 168 of the second scan 164, the third flip flop 143 and the OR gate 146 of FIG. 1B cause the gating circuit 140 to output the clock pulses 117 in the scan window 168 of the third scan 164. The selective scan clock gating (e.g., in the third state 153 in FIG. 1C) advantageously allow scan operation to test the scan chain storage devices 109 of a given scan chain 118 (or group of scan chains 118 as shown in FIGS. 1G and 1H), while selectively turning the storage device clocking off (clock gating) to conserve power and avoid switching losses associated with scan chains 118 that are not being evaluated in a current scan 164.

In addition, the illustrated gating circuits 140 (FIG. 1B) selectively provide clock signals at the output 117 to the scan chain storage devices 109 of the given scan chain 118 (or scan chain groups) in response to a capture pulse (e.g., in the capture window 168) of a given scan 164 to allow the system to clock out (e.g., shift out) the scan chain data to the compressor 110 via the mask 112 (FIG. 1). This facilitates capture and identification of failure conditions (e.g., inter-domain failures) in the design logic 108 of the electronic device 104 being tested, for example, to provide suitable clock pulses at the output 117 irrespective of the value LPGREG of the pattern gating register 130.

FIG. 1E shows an example distributed clock gating circuitry in the electronic device 104 to further facilitate reduced power consumption associated with scan chain storage device clock signals during self-testing. This example can reduce hold timing closure in stuck-at test mode failures in the design logic 108 (FIG. 1). The electronic device 104 being tested, such as a system on chip (SoC) is divided into several domains having associated scan chains 118 and/or groups thereof (e.g., FIGS. 1G and 1H). A capture pulse is propagated into the domain by the clock generator 148 (e.g., FIG. 1B), and the scan enable signal SCANEN in one example is controlled from a one-hot capture decoder 122, which operates to provide a capture pulse to only one domain at a time. This can further reduce power consumption during testing, while still allowing identification and capture of faults in the design logic 108 (FIG. 1) including inter-domain faults.

The clock gating circuit 116 and the gating circuits 140 of the described examples advantageously provide a low area overhead solution to facilitate power reduction during self-testing of the electronic device 104. Other solutions can reduce power, such as using segmented scans, staggered clocks, inverted clocks, multiple scan segments, output gating of scan flip-flops, alone or in combination with low power gating (LPG). Low power gating itself gates the inputs or heads of the scan chains to restrict the inputs to a constant value for the duration of a scan pattern and thereby helps to reduce scan data based toggles and shift power. However, low power gating alone does not reduce clock power for self-testing. The described clock gating circuit 116 of the illustrated examples provides a solution to further reduce testing power by mitigating unneeded clocking of the scan chains 118 without having to add additional power pads, lower power grid resistance, and/or add additional decoupling capacitors. These alternate approaches can adversely impact the electronic device package pins, impact routing resources, and generally suffer from increased device die size. In contrast, the described examples provide reduced power consumption without sacrificing self-test coverage, with little or no increase in device size (area). In addition, the described solutions are compatible with advanced compression schemes for test data volume reduction without incurring significant area overhead. Example implementations can facilitate direct blocking of the shift clock for scan chains 118 which do not receive any capture clock and provide pattern dependent gating to allow identification of inter domain faults resulting in enhanced test coverage.

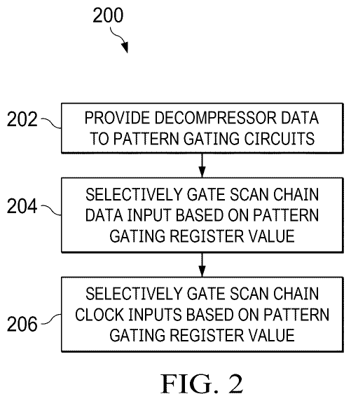

FIG. 2 shows a method 200 of manufacturing a tested electronic device 104, including automated self-testing in certain implementations. The method 200 in one example includes providing decompressor data two pattern gating circuits at 202 (e.g., via the decompressor 106 in FIG. 1), as well as selectively gating a scan chain data input at 204 in FIG. 2 for a scan chain 118 of the electronic device 104 based on the value (LPGREG, H or L) of the pattern gating register 130 of the electronic device 104. At 206 in FIG. 2, the method 200 further includes selectively gating 206 the storage element clock inputs of the scan chain 118 based on the value LPGREG of the pattern gating register 130. In one example (e.g., FIGS. 1-1H) the electronic device 104 includes a clock gating circuit (116 in FIGS. 1 and 1B) with a finite state machine 150 (FIG. 1C) with respective first and second states 151 and 152 that couple the system clock 120 of the electronic device 104 to the storage element clock inputs during a scan 164, as well as a third state 153 that prevents coupling of the system clock 120 to the storage element clock inputs during the scan 164.

In this example, the selective storage element clock gating includes transitioning the finite state machine 150 from the first state 151 to the second state 152 in response to the pattern gating register 130 having a first value (e.g., H) in a current scan 164, transitioning the finite state machine 150 from the second state 152 to the first state 151 in response to the pattern gating register 130 having a different second value L in the current scan 164, transitioning the finite state machine 150 from the second state 152 to the third state 153 in response to the pattern gating register 130 having the first value H in the current scan 164, and transitioning the finite state machine 150 from the third state 153 to the first state 151 in response to the pattern gating register 130 having the second value L in the current scan 164. In one or more implementations, the electronic device 104 can includes a pattern gating circuit 114 configured to selectively allow or prevent transfer of scan data to the scan chain data input of the scan chain 118 based on the value of the pattern gating register 130, and selectively gating the scan chain data input at 206 includes loading the first value H into the pattern gating register 130 in a current scan 164.

In this or another example, the electronic device 104 can include a pattern gating circuit 114 that is configured to selectively prevent transfer of scan data to the scan chain data input of the scan chain 118 in response to the pattern gating register 130 having a first value H in a current scan 164 and to allow transfer of scan data to the scan chain data input of the scan chain 118 in response to the pattern gating register 130 having a second value L in the current scan 164. In this example, the clock gating circuit 116 can be configured to selectively prevent coupling of a system clock 120 to the storage element clock inputs during the current scan 164 based on the value of the pattern gating register 130, where the selective scan chain data input scanning at 204 includes loading the first value H into the pattern gating register 130 in the current scan 164.

In certain implementations, moreover, the selective storage element clock gating at 206 can include loading the first value H into the pattern gating register 130 in two consecutive scans 164. In various implementations, the clock gating circuit 116 can be configured to couple the system clock 120 to the storage element clock inputs in response to a capture pulse associated with the scan chain 118.

The example electronic devices 104, test systems 100, and methods 200 can provide significant advantages with respect to reducing power during self-testing of the electronic device 104. In one example implementation, using a sample design for stuck-at fault model, the described apparatus and techniques can provide a clock power reduction more than 60 percent compared to a non-gated low power gating (LPG) design with the same test coverage. The described solutions, moreover, are versatile and can be adopted for any digital electronic device, including system on chip (SoC) designs with low power gating for reduction in clock power during scan operation. The power savings during scan operation facilitate increased test speeds, for example, running a structural test at 10 % higher rate. In one example implementation, a 10 % higher shift frequency can be used (e.g., increased clock rate), resulting in reduction of the structural test time by 10 %. In this non-limiting example, reduced testing time can provide an estimated total expected savings of approximately 10-20 % of scan test time which is significant for large digital designs.

Modifications are possible in the described examples, and other implementations are possible, within the scope of the claims.

What is claimed is:

1. An electronic device, comprising:
a scan chain having a scan chain data input and storage elements with respective storage element clock inputs;
a pattern gating circuit having a pattern gating register; and
a clock gating circuit configured to selectively prevent coupling of a system clock to the storage element clock inputs during a scan of the scan chain based on a value of the pattern gating register.

2. The electronic device of claim 1, wherein the clock gating circuit is configured to couple the system clock to the storage element clock inputs in response to a capture pulse associated with the scan chain.

3. The electronic device of claim 1, wherein the clock gating circuit includes a first input coupled to the system clock, a second input coupled to the pattern gating register, and an output coupled to the storage element clock inputs.

4. The electronic device of claim 1, wherein the clock gating circuit is configured to prevent coupling of the system clock to the storage element clock inputs in response to the pattern gating register having a first value for two consecutive scans.

5. The electronic device of claim 4, wherein the pattern gating circuit is configured to selectively prevent transfer of scan data to the scan chain data input of the scan chain in response to the pattern gating register having the first value in a current scan.

6. The electronic device of claim 4, wherein the clock gating circuit is configured to couple the system clock to the storage element clock inputs in response to a capture pulse associated with the scan chain.

7. The electronic device of claim 4, wherein:
the clock gating circuit includes a finite state machine with first and second states that couple the system clock to the storage element clock inputs during the scan and a third state that prevents coupling of the system clock to the storage element clock inputs during the scan;
the finite state machine is configured to transition from the first state to the second state in response to the pattern gating register having the first value in a current scan;
the finite state machine is configured to transition from the second state to the first state in response to the pattern gating register having a different second value in the current scan;
the finite state machine is configured to transition from the second state to the third state in response to the pattern gating register having the first value in the current scan; and
the finite state machine is configured to transition from the third state to the first state in response to the pattern gating register having the second value in the current scan.

8. The electronic device of claim 1, wherein:
the clock gating circuit includes a finite state machine with first and second states that couple the system clock to the storage element clock inputs during the scan and a third state that prevents coupling of the system clock to the storage element clock inputs during the scan;
the finite state machine is configured to transition from the first state to the second state in response to the pattern gating register having the first value in a current scan;
the finite state machine is configured to transition from the second state to the first state in response to the pattern gating register having a different second value in the current scan;
the finite state machine is configured to transition from the second state to the third state in response to the pattern gating register having the first value in the current scan; and
the finite state machine is configured to transition from the third state to the first state in response to the pattern gating register having the second value in the current scan.

9. A system, comprising:
automatic test equipment (ATE) having a scan data output; and
a tested device, including:
a decompressor coupled to the scan data output of the ATE;
a scan chain having a scan chain data input and storage elements with respective storage element clock inputs;
a pattern gating circuit coupled to the scan data output of the decompressor and having a pattern gating register; and
a clock gating circuit configured to selectively prevent coupling of a system clock to the storage element clock inputs during a scan of the scan chain based on a value of the pattern gating register.

10. The system of claim 9, wherein the clock gating circuit is configured to couple the system clock to the storage element clock inputs in response to a capture pulse associated with the scan chain.

11. The system of claim 9, wherein the clock gating circuit includes a first input coupled to the system clock, a second input coupled to the pattern gating register, and an output coupled to the storage element clock inputs.

12. The system of claim 9, wherein the clock gating circuit is configured to prevent coupling of the system clock to the storage element clock inputs in response to the pattern gating register having a first value for two consecutive scans.

13. The system of claim 12, wherein the pattern gating circuit is configured to selectively prevent transfer of scan data to the scan chain data input of the scan chain in response to the pattern gating register having the first value in a current scan.

14. The system of claim 9, wherein:
the clock gating circuit includes a finite state machine with first and second states that couple the system clock to the storage element clock inputs during the scan and a third state that prevents coupling of the system clock to the storage element clock inputs during the scan;
the finite state machine is configured to transition from the first state to the second state in response to the pattern gating register having the first value in a current scan;
the finite state machine is configured to transition from the second state to the first state in response to the pattern gating register having a different second value in the current scan;
the finite state machine is configured to transition from the second state to the third state in response to the pattern gating register having the first value in the current scan; and
the finite state machine is configured to transition from the third state to the first state in response to the pattern gating register having the second value in the current scan.

15. A method of manufacturing a tested electronic device, the method comprising:
selectively gating a scan chain data input of a scan chain of the electronic device based on a value of a pattern gating register of the electronic device; and
selectively gating storage element clock inputs of the scan chain based on the value of the pattern gating register.

16. The method of claim 15, wherein:
the electronic device includes a clock gating circuit with a finite state machine having first and second states that couple a system clock of the electronic device to the storage element clock inputs during a scan and a third state that prevents coupling of the system clock to the storage element clock inputs during the scan; and
selectively gating the storage element clock inputs of the scan chain includes:
transitioning the finite state machine from the first state to the second state in response to the pattern gating register having a first value in a current scan;
transitioning the finite state machine from the second state to the first state in response to the pattern gating register having a different second value in the current scan;
transitioning the finite state machine from the second state to the third state in response to the pattern gating register having the first value in the current scan; and
transitioning the finite state machine from the third state to the first state in response to the pattern gating register having the second value in the current scan.

17. The method of claim 16, wherein:
the electronic device includes a pattern gating circuit configured to selectively allow or prevent transfer of scan data to the scan chain data input of the scan chain based on the value of the pattern gating register; and
selectively gating the scan chain data input of the scan chain includes loading the first value into the pattern gating register in a current scan.

18. The method of claim 15, wherein:
the electronic device includes:
a pattern gating circuit configured to selectively prevent transfer of scan data to the scan chain data input of the scan chain in response to the pattern gating register having a first value in a current scan and to allow transfer of scan data to the scan chain data input of the scan chain in response to the pattern gating register having a second value in the current scan; and
a clock gating circuit configured to selectively prevent coupling of a system clock to the storage element clock inputs during the current scan based on the value of the pattern gating register; and
selectively gating the scan chain data input of the scan chain includes loading the first value into the pattern gating register in the current scan.

19. The method of claim 18, wherein selectively gating the storage element clock inputs of the scan chain includes loading the first value into the pattern gating register in two consecutive scans.

20. The method of claim 18, wherein the clock gating circuit is configured to couple the system clock to the storage element clock inputs in response to a capture pulse associated with the scan chain.
